(19) United States
(12) Patent Application Publication
(10) Pub. No.: US 2006/0051893 A1
(43) Pub. Date: Mar. 9, 2006

(54) Thin substrate support

(75) Inventors: Michel Puech, Metz-Tessy (FR); Xavier Guichenal, Chilly (FR)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 11/219,651

(22) Filed: Sep. 7, 2005

(30) Foreign Application Priority Data
Sep. 8, 2004 (FR) 0451992

(51) Int. Cl. H01L 21/50; H01L 21/48

(52) U.S. Cl. 438/107

(57) ABSTRACT

A device for supporting a semiconductor substrate device comprises a sample-holder attached to a treatment chamber including a cooling system and electrical connection means. The device further comprises an intermediate element fixed to the sample-holder by electrostatic means or by means of clamps and electrically and thermally connected to the sample-holder. The intermediate element is removable, has sufficient stiffness to allow manipulation of a thinned substrate that it supports and includes a base consisting of a first material having a higher conductivity than the substrate. A first layer covering the base consists of a second material having a high dielectric strength. First and second electrodes are disposed on the first layer. A second layer covering the first layer and the electrodes consists of a third material having a high dielectric strength.

### CROSS-REFERENCE TO RELATED APPLICATIONS

This application is based on French Patent Application No. 0451992 filed Aug. 9, 2004, the disclosure of which is hereby incorporated by reference thereto in its entirety, and the priority of which is hereby claimed under 35 U.S.C. §119.

### BACKGROUND OF THE INVENTION

1. Field of the Invention

The present invention relates to the field of plasma treatment of semiconductor substrates, in particular etching and/or plasma deposition. The invention relates more precisely to a support intended for substrates whose thickness is less than 500 μm.

2. Description of the Prior Art

In the semiconductor industry, the manipulation of substrates in the form of wafers represents an important aspect of the fabrication process. Following the production of integrated circuits on thick semiconductor substrate wafers, for example silicon wafers, the latter must be thinned by mechanical action to the thickness required for their application.

This thinning has two consequences:

a) thinned to thicknesses of the order of 100 μm or less, substrates that were previously rigid become flexible and are then very difficult to manipulate;

b) the mechanical action modifies the structure of the material to a depth from 10 μm to 30 μm: the structure of the substrate, which was monocrystalline, becomes amorphous. The thinned substrate therefore has to undergo a subsequent treatment to remove this layer.

In one prior art thinning method, the front face of the wafer on which the integrated circuits have been produced is covered with a plastics material film. The wafer is then introduced into a grinding machine in which it is thinned by mechanical action on its rear face. The thinned wafer then undergoes a second treatment to remove the surface layer that has been modified by thinning, by means of a mechanical or chemical polishing action.

Following the above two steps, the thinned face of the semiconductor substrate is fixed to a support consisting of a plastics material film supported by a metal frame. The plastics material film is then removed from the front face of the substrate. The supported film/substrate assembly is then introduced into a sawing machine in which the saw blade penetrates the whole of the thickness of the substrate, passing through all the cutting lines, to individualize the circuits, which remain fixed to the plastics material film. The supported film/substrate assembly is then removed from the sawing machine and the circuits are ready to be mounted in their packaging. The main drawback of this method is that it generates silicon flakes at the edges of the circuits. These flakes produced by the saw blade are the origin of defects that can go so far as breaking of the circuit.

A variant of the above method known as dicing by grinding (DBG) or dicing by thinning (DBT) reduces the number of defects generated by the saw blade but does not eliminate them entirely. Before the thinning operation, the thick semiconductor substrate wafer is partially sawn from its front face, the saw blade penetrating into the substrate only to a depth slightly greater than the final thickness of the substrate. The front face of the wafer is then covered with a protective plastics material film and the thick wafer is introduced into the grinding machine to be thinned therein by mechanical action as far as the bottom of the saw cuts. The circuits are therefore separated and retain the form of a thinned substrate wafer that is thereafter polished mechanically or chemically to remove the layer that has become amorphous.

A new technique was subsequently introduced consisting in replacing the saw used for mechanical separation of the circuits by machining or plasma etching a trench between the circuits. Plasma etching being an action that entails removing material by a physico-chemical phenomenon, there is no risk of generating defects of mechanical origin. Minimum defects therefore result from this operation. Plasma etching may advantageously replace the saw blade for separating the circuits, whether before or after thinning, and also replace polishing techniques for removing the layer of silicon that has become amorphous after thinning by grinding.

In the plasma etching technique, a step of photolithography is applied to one of the faces of the semiconductor substrate, thereby delimiting the areas that will be exposed to the plasma, and therefore etched, from those which will be protected from the plasma by the photosensitive resin mask. The semiconductor substrate is placed on a sample-holder placed in an enclosure. A plasma is created within this enclosure in a low-pressure gas containing for example fluorine, such as SF₆. At the same time, the sample-holder is negatively polarized to accelerate the bombardment of the surface of the substrate by the positive ions, which accelerates the etching of the material and accentuates the verticality of the etch.

During etching, the substrate is subjected to heat, which raises its surface temperature. To avoid damaging the photosensitive resin etching mask and the electronic circuits present in the substrate, the substrate must be cooled throughout the etching operation to maintain its temperature at a value below 80° C. to 100° C. To cool the substrate, it is held in contact by mechanical or electrostatic means with the surface of the sample-holder, which is provided with a cooling system, and helium gas is injected between the upper face of the sample-holder and the lower face of the substrate. This gas conveys heat from the substrate to the sample-holder.

To be thermally efficient, the pressure of the helium must be greater than approximately 10 mbar. Although this pressure does not cause problems in the case of thick substrates, it tends to deform thinned substrate wafers, especially when they consist of individualized circuits. It is therefore essential to fix the substrate wafers reversibly to a rigid support after thinning.

A first technique consists in fixing the thinned substrate wafer to a rigid support using an adhesive polymer film.

Fixing the thinned substrate to a semiconductor substrate of standard thickness by means of a film (known as thermal tape) that has the property of losing its adhesion properties when it is subjected to a high temperature has been suggested, and this should enable the individualized circuits to be picked off. In practice it is very difficult to separate the circuits from their support without destroying them completely, the film, once heated, retaining greater adhesion than the mechanical strength of the thin silicon.

Fixing the thinned substrate to a rigid piece of quartz approximately 1 mm thick by means of a film (known as UV tape) that has the property of losing its adhesion qualities when it is irradiated through the quartz by ultraviolet radiation has also been envisaged. This technique has two major drawbacks. Firstly, quartz is a very poor conductor of heat (its thermal conductivity is 1 W/m.K) compared to silicon (156 W/m.K). Its thermal resistance is therefore very high, and the surface of the silicon substrate quickly reaches a temperature in excess of 80° C. to 100° C. The only solution is then to reduce the etching speed, which is to the detriment of productivity. The quartz is then electrically insulative and this means that the substrate cannot be retained on the sample-holder by electrostatic means.

A second technique consists in fixing the thinned substrate wafer to a mobile support by electrostatic means.

The document US-2002/110,449 proposes to hold the substrate onto a transportable support to which it remains fixed during and between the process steps. This support comprises a dielectric material in the form of a ceramic such as quartz, glass, aluminum or titanium oxides, and barium titanate. It integrates the electrical circuits for generating and accumulating the electrical charges that generate the electrostatic force.

This system has two major drawbacks. Firstly, the 0.3 mm to 2.5 mm thick ceramic has a high thermal resistance. If the transportable support is held onto the sample-holder by mechanical means, the pressure of the helium deforms the thin ceramic at its center. This deformation causes uneven heat transfer (more heat is transferred at the center) and a very high risk of degrading the silicon substrate that suffers this deformation.

Thereafter, the electrodes being charged before the next process step, the electrostatic system can operate only if the electric charges accumulated in the electrodes remain therein throughout the operation. In the present situation of an operation of dry etching in a vacuum using a plasma medium and alternating polarization of the substrate at frequencies from 30 kHz to 13.56 MHz, electrodes that are not energized permanently may become discharged, leading to loss of the electrostatic force retaining the substrate.

The document US-2004/037,692 describes a mobile substrate-holder intended to resist treatment of a substrate during which the temperature of the substrate can exceed 400° C. (for example depositing a metal on its rear face or welding the substrate to a base). The substrate-holder includes a base preferably consisting of a ceramic semiconductor material (ALO2, Kapton, SiC) whose thermal conductivity is not very high covered with a layer of insulative material (SiO₂, Si₃N₄). This substrate-holder designed to be used at high temperatures is not capable of cooling a substrate efficiently to maintain it at temperatures below 80° C.

Also, the substrate is held onto the substrate-holder by an electrostatic system that does not necessitate an external energization during the treatment. This system consists of metal electrodes disposed in a functional layer of a material containing mobile ions (borosilicate glass) or having a high dielectric constant (barium titanate or strontium titanate). To fix the substrate, an electrical voltage is applied to the terminals of the two electrodes. The mobile ions are displaced by the applied electric field and create individual electrical dipoles. The sum of the individual electrical fields generated by the dipoles creates a high field that remains after the electrical voltage has been removed. It is this remnant electric field that holds the substrate on the substrate-holder during the treatment.

This solution cannot be used in the present situation of an operation of dry etching in a vacuum plasma medium with alternating polarization of the substrate at frequencies from 30 kHz to 13.56 MHz because the effect of the alternating voltage is that the electrical dipoles are overturned, canceling the electrical field fixing the substrate, which is no longer held onto the substrate-holder.

U.S. Pat. No. 6,268,994 discloses a chuck adapted to support a sample, provided with a cooling system and consisting of two portions, a conductive base and a frame, fastened together by bolts inserted into orifices in the conductive base. The two portions are connected electrically and thermally. The junction between the conductive base and the frame may be effected by means of an epoxy adhesive, a thermally conductive grease or brazing. The sample is fixed electrostatically to the base which consists of a conductive portion covered successively by a first insulative layer, a conductive layer, and a second insulative layer. This chuck does not solve the problem of manipulating thin or fragile samples.

The present invention proposes a device that does not have the drawbacks of the prior art devices and is adapted to support a thinned semiconductor substrate wafer for treatment thereof in a vacuum using a plasma medium. In particular, the device of the invention provides a rigid support for the substrate that is fastened to the substrate and removable therefrom to enable it to be manipulated easily. Furthermore, the device of the invention is able to maintain the temperature of the substrate below 80° C. throughout the treatment. Finally, the device of the invention must allow, after treatment, easy and total releasing of the substrate, where applicable cut up to form circuits.

### SUMMARY OF THE INVENTION

The invention consists in a device for supporting a semiconductor substrate, the device comprising a sample-holder attached to a treatment chamber including a cooling system and electrical connection means, wherein the device further comprises an intermediate element fixed to the sample-holder by electrostatic means or by means of clamps and electrically and thermally connected to the sample-holder, the intermediate element being removable, having sufficient stiffness to allow manipulation of a thinned substrate that it supports, and including

a base consisting of a first material having a higher conductivity than the substrate,

a first layer covering the base and consisting of a second material having a high dielectric strength,

first and second electrodes disposed on the first layer, and

a second layer covering the first layer and the electrodes and consisting of a third material having a high dielectric strength.

The intermediate element is removable and has sufficient stiffness to allow manipulation of a thinned substrate that it supports.

The device of the invention advantageously allows frequencies of fixing the combination of the intermediate element and the thin substrate to the sample-holder and separating it therefrom that are of the same order of magnitude as for a substrate alone. The invention allows the use of unmodified standard equipment (robot arm, chamber doors, substrate-holder, transport cassettes, etc.) and cools the intermediate element by means of the conventional cooling system consisting in injecting helium under the intermediate element at a reasonable leakage rate.

The intermediate element-substrate assembly obtained in the above way has dimensions of the same order of magnitude as the substrate alone prior to thinning, that is to say a diameter of 150 mm or 200 mm, a thickness of the same order of magnitude as that of the substrate before thinning, and a weight of less than 500 g. The intermediate element-substrate assembly is light and easily transportable without risk of damaging the thinned substrate.

The material constituting the base of the intermediate element must have a much higher thermal conductivity than the substrate, and preferably a thermal conductivity that is as high as possible, to facilitate the evacuation of the heat generated by the plasma treatment of the substrate to the cooled sample-holder. In a first embodiment of the invention, the first material is a metal, preferably copper or aluminum.

A first layer of a dielectric material insulates the electrodes from the base. This material must be capable of resisting without breakdown voltages of a few kilovolts. The material constituting the first layer must also have as high a thermal conductivity as possible so as not to create a thermal barrier between the substrate and the base of the intermediate element. These two criteria must be optimized simultaneously, if possible, of course. In a second embodiment, said second material is an aluminum oxide Al₂O₃, for example a layer of anodized aluminum formed on the surface of the base or of the electrodes, depending on which of these is made of aluminum.

This first insulative layer is in contact with the electrodes. For example, the electrodes may take the form of a thin layer of an electrically conductive material, obtained in particular by depositing a conductive material onto the first insulative layer. In a third embodiment, the electrodes are of metal, preferably copper or aluminum.

The electrodes are covered with a second insulative layer that is capable of resisting without breakdown voltages of a few kilovolts and is a very good conductor of heat in order to contribute to cooling the substrate. The material selected for this second insulative layer has to meet electrical and thermal criteria similar to those applying to the material of the first insulative layer. However, as this material is locally subjected to the degrading action of the plasma, it is advantageous to use a material that can be removed and replaced easily. In a fourth embodiment, the third material is a flexible polymer. In one variant the flexible polymer is, an adhesive polymer. In another variant, the flexible polymer is selected from polytetrafluoroethylene (PTFE), a polyvinylchloride (PVC), a polyethylene (PE) and a polyamide (PA).

The second insulative layer may consist of a polymer film, for example, which is preferably adhesive on the side in contact with the electrodes, or a material that may be deposited by means of a spinner and removed chemically using appropriate solvents, for example a polyamide. It is also important that the surface of the upper face of this insulative layer be perfectly flat so as not to generate stresses in the thinned substrate it is to hold.

The device of the present invention has many advantages. Firstly, the intermediate element may be made from a material that is inexpensive compared to quartz, such as an aluminum disc. Secondly, it is not sensitive to defects, such as scratches, that damage quartz and cause it to lose some of its transparency. Thirdly, it does not necessitate a particular environment, such as non-actinic light in the case of quartz and films sensitive to ultraviolet radiation. Finally, in the event of wear, it is very easy to replace the upper dielectric, in particular if it is a polymer film or was deposited by means of a spinner.

In one embodiment of the invention, the substrate is fixed to the intermediate element by electrostatic means and the intermediate element is fixed to the sample-holder by electrostatic means. The sample-holder comprises electrodes between which an electrical voltage of a few kilovolts is applied so that the intermediate element is held against the sample-holder by the electrostatic pressure resulting from the application of the electrical voltage. Fixing the intermediate element to the sample-holder by electrostatic means is similar to fixing the substrate to the intermediate element as described above. An electrical voltage of a few kilovolts is applied between the electrodes so that the intermediate element is held against the sample-holder.

In this case, the intermediate element is preferably a disc whose diameter is of the same order of magnitude as the dimension of the substrate.

In another embodiment, the substrate is fixed to the intermediate element by electrostatic means and the intermediate element is fixed to the sample-holder by means of clamps. The term “clamp” means any fixing means that exert a force on the intermediate member and have the effect of pressing the intermediate member onto the sample-holder, it being possible to separate the intermediate element from the sample-holder simply by neutralizing this force. Fixing means of this type are described in the document EP-1 263 025 in particular.

In this embodiment, the intermediate element is a disc whose diameter is slightly greater than the dimension of the substrate, to provide a bearing area for the clamps.

In this case, said base preferably has a thickness of at least 1 mm, and more preferably from 1 mm to 2 mm, to enable it to be gripped between the jaws of the clamps.

According to a first aspect of the invention, a film of pressurized helium is formed between the intermediate element and the sample-holder. A flow of helium, used as an inert gas enabling heat exchange, is directed against the upper face of the sample-holder and the lower face of the intermediate element, in order to sweep it with the gas and to form a permanent gas film.

According to a second aspect, a film of pressurized helium is formed between the intermediate element and the substrate. Helium is also introduced between the upper face of the intermediate element and the lower face of the substrate.

To provide efficient heat transfer, the helium pressure must be at least 10 mbar.

Because of the plasma, which is a gaseous and electrically conductive medium, the electrostatic pressure is re-established immediately the gases are admitted. Because of the electrostatic pressure, the silicon substrate is pressed against the intermediate element and the heat generated at its surface is evacuated under optimum conditions. At the end of the treatment, admission of the gases and the plasma are stopped, and the electrical voltage is removed from the contacts of the intermediate element. The intermediate element carrying the thinned substrate is then removed from the machine.

If necessary, the intermediate element-substrate assembly may be placed outside the machine on a member provided, like the sample-holder, with two electrical contacts between which there is applied a voltage of the opposite sign to that used for retaining the substrate. The substrate is at this stage completely released and ready for the next step.

In one particular embodiment of the invention, the first electrode is substantially in the shape of a disc and the second electrode is substantially in the shape of a ring surrounding the first electrode. In order to establish electrical continuity with the sample-holder, each of the electrodes includes a respective extension covered with the first layer to insulate it from the base of the intermediate element through which it passes as far as its rear face to define two electrical contact points. Outside the plasma treatment machine, the substrate is placed on an intermediate element provided with two electrical contacts facing the contacts of the sample-holder. An electrical voltage of a few kilovolts is applied between the two electrodes for a few minutes. The substrate is then held against the intermediate member by the electrostatic pressure resulting from the application of the electrical voltage. The intermediate element-substrate assembly is then inserted into the machine and fixed to the sample-holder by electrostatic means or by means of clamps that are easy to open. As soon as it is placed on the sample-holder, electrical continuity is established between the contacts of the intermediate element and those of the sample-holder and a voltage of a few kilovolts is established between the electrodes.

In another embodiment of the invention, the intermediate element further comprises:

a third layer covering said base on the side opposite the first layer, consisting of a fourth material having a high dielectric strength,

third and fourth electrodes disposed on the third layer, and

a fourth layer covering the third layer and the third and fourth electrodes, consisting of a fifth material having a high dielectric strength.

The third insulative layer has the same function as the first insulative layer on the opposite side of the base, i.e. to insulate the electrodes electrically from the base. The fourth material must therefore have characteristics similar to those of the second material constituting the first insulative layer. The fourth material is preferably an aluminum oxide Al₂O₃, for example a layer of anodized aluminum formed on the surface of the base or of the electrodes, depending on which of them are made of aluminum.

For example, the third and fourth electrodes may take the form of a thin layer of an electrically conductive material obtained in particular by depositing conductive material onto the third insulative layer. The electrodes are advantageously made of metal, preferably copper or aluminum.

The fourth insulative layer has the same function as the second insulative layer on the opposite side of the base. The fifth material must therefore have characteristics similar to those of the third material constituting the second insulative layer. The second material is preferably a flexible polymer. In one variant the flexible polymer is an adhesive polymer. In another variant the flexible polymer is selected from polytetrafluoroethylene (PTFE), a polyvinylchloride (PVC), a polyethylene (PE) and a polyamide (PA).

In one particular embodiment of the invention, the third electrode is substantially the shape of a disc and the fourth electrode is substantially the shape of a ring surrounding the third electrode. To establish electrical continuity with the sample-holder, each electrode has an extension covered with the third layer that insulates it from the base of the intermediate element through which it passes as far as its rear face, to define two electrical contact points. The extension of the third electrode is advantageously common with that of the first electrode and the extension of the fourth electrode is advantageously common with that of the second electrode. In this way the intermediate element has only two points of electrical contact with the sample-holder.

The present invention further provides a method of manipulating a semiconductor substrate by means of a device as described above. The method comprises the following steps:

the substrate is fixed to an intermediate element by electrostatic means,

the intermediate element carrying the substrate is introduced into a treatment chamber,

the intermediate element is fixed to a sample-holder, attached to the chamber, including a cooling system and means for electrical connection to the intermediate element,

the substrate is treated in a plasma medium in a vacuum,

the sample-holder is detached from the intermediate element carrying the treated substrate,

the substrate is removed from the intermediate element.

The intermediate element is preferably fixed to the sample-holder electrostatically. An electrical voltage of a few kilovolts is applied between the electrodes so that the intermediate element is held against the sample-holder. The intermediate element may also be fixed to the sample-holder by means of clamps.

The present invention has the advantage that it allows plasma treatment of thin substrates without damaging them under optimum conditions in terms of treatment speed. Firstly, the temperature of the substrates may be maintained at a value below around 80° C. whilst at the same time allowing high treatment speeds. Secondly, this enables the individualized circuits to be taken up without effort, and thus without damage, after their separation. Finally, the substrate is not subjected to any hazardous manipulation before or after the plasma treatment, unlike methods of fixing thinned substrates to a quartz support with films sensitive either to temperature or to ultraviolet radiation.

### BRIEF DESCRIPTION OF THE DRAWING

Other features and advantages of the present invention will become apparent in the course of the following description of embodiments given by way of non-limiting example, and in the appended drawing in which:

FIG. 1 shows the device of the present invention including an intermediate element conforming to one embodiment of the invention,

FIG. 2 shows a variant of the FIG. 1 embodiment,

FIG. 3 shows an intermediate element conforming to another embodiment of the invention.

### DETAILED DESCRIPTION

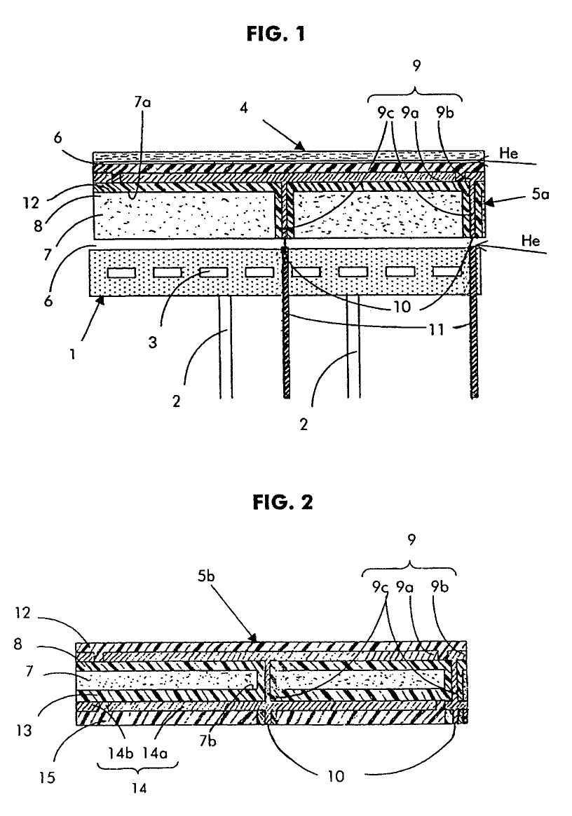

As shown in FIG. 1, the device of the invention comprises a sample-holder 1 attached to a treatment chamber and provided with a cooling system comprising tubes 2 for supplying it with heat-exchange fluid and evacuating the fluid to a heat exchange device, for example, and passages 3 for this fluid. A substrate 4 fixed to an intermediate element 5a is placed on the sample-holder 1. An inert heat-exchange gas such as helium is injected between the upper face of the sample-holder 1 and the lower face of the intermediate element 5a and between the lower face of the substrate 4 and the upper face of the intermediate element 5a to form a thin layer 6.

The intermediate element 5a, here in the shape of a disc, comprises a base 7 consisting of a material that is a very good conductor of heat, such as a metal, for example copper (thermal coefficient Cₜₕ=401 W/m.K) or aluminum (Cₜₕ=237 W/m.K). The thermal conductivity of the material constituting the base 7 must be high, and much higher than that of the substrate 4, to transfer to the helium layer 6 heat generated in the substrate 4 by the plasma treatment.

The base 7 is preferably of aluminum. The face 7a of the base 7 on the side intended to receive the substrate is covered with a layer 8 of an insulative material having a high dielectric strength, for example alumina Al₂O₃. This insulative layer may be obtained in particular by anodizing the aluminum of the upper surface of the base 7. The layer 8 is covered with a conductive layer 9 constituting electrodes. The function of the layer 8 is to insulate the material of the base 7 electrically from the conductive layer 9. The discontinuous conductive layer 9, which is a few microns thick, is preferably a layer of copper. The conductive layer 9 comprises two concentric electrodes, one having the shape of a central disc 9a surrounded by the second having the shape of a ring 9b. This conductive layer 9 has two extensions 9c that are electrically insulated from the base 7 by the layer 8; one extends the central disc 9a and the other, at the periphery, extends the ring 9b. These extensions 9c emerge at the rear face of the intermediate element 5a to define two electrical contact areas 10. Once the intermediate element 5a has been placed on the sample-holder 1, these areas 10 are in contact with the ends of two corresponding electrical connections 11 that emerge from the sample-holder 1, enabling an electrical voltage to be applied between the electrodes 9a and 9b.

The conductive layer 9 is protected by a second insulative layer 12 of a material having a high dielectric strength. In the present example a film of polyethylene terephthalate (PET) from 70 μm to 170 μm thick is used that is adhesive on its lower side in contact with the upper face of the conductive layer 9.

In this embodiment, the intermediate element 5a has the same diameter D as the substrate 4. The base 7 and each of the layers 8, 9, 12 that cover it have the same diameter D. The intermediate element 5a may be fixed to the sample-holder 1 by electrostatic means using electrodes (not shown) incorporated in the sample-holder 1, in the same way as the substrate 4 is fixed to the intermediate element 5a.

FIG. 2 represents an intermediate element 5b conforming to a variant of the preceding embodiment. A third insulative layer 13 is deposited on the face 7b of the base 7 on the side opposite the substrate and not covered by the first insulative layer 8. The insulative layer 13 has characteristics similar to those of the layer 8. It consists of an insulative material having a high dielectric strength, for example alumina Al₂O₃.

A discontinuous conductive layer 14 a few microns thick, and preferably of copper, is deposited on the insulative layer 13. The conductive layer 14 comprises two concentric electrodes, one having the shape of a central disc 14a surrounded by the second having the shape of a ring 14b. The electrodes 14a and 14b are electrically connected to the extensions of the electrodes 9a and 9b, respectively, and emerge from the intermediate element via the contact areas 10.

The conductive layer 14 is protected by a fourth insulative layer 15 of a material having a high dielectric strength. Like the second layer 12, the insulative layer 15 may consist of a polyethylene terephthalate (PET) film 70 μm to 170 μm thick that is adhesive on its lower side in contact with the upper face of the conductive layer 14.

In this embodiment, the intermediate element 5b has the same diameter D as the substrate 4. The base 7 and each of the layers 13, 14, 15 that cover it has the same diameter D. The intermediate element 5b may be fixed to the sample-holder 1 by electrostatic means using the electrodes 14a and 14b incorporated in the intermediate element 5b, in the same way as the substrate 4 is fixed to the intermediate element 5b by electrostatic means by the electrodes 9a and 9b that are also incorporated in the intermediate element 5b.

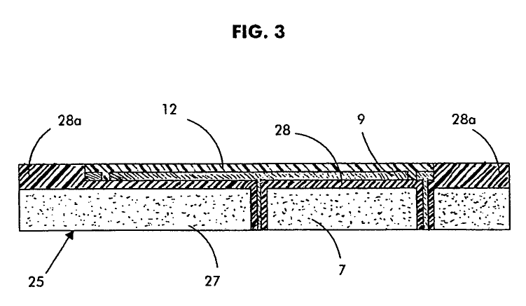

In the embodiment of the invention shown in FIG. 3, items similar to those in FIG. 1 are designed by the same reference number. This embodiment differs from that of FIG. 1 in that the intermediate element 25 has a diameter D′ greater than that of the substrate 4 in order to enable it to be fixed by clamps to the sample-holder 1. This mode of fixing is described in the document EP-1 263 025 in particular. The base 27 and the first insulative layer 28 have the same diameter D′ as the element 25. The conductive layer 9 and the second insulative layer 12 have the same diameter D as the substrate 4. The first insulative layer 28 therefore has an increased thickness portion 28a at its periphery that is equal to the sum of the thicknesses of the layers 9 and 12, in order to make good the difference in diameter. The means for fixing the element 25 to the sample-holder 1 bear on this increased thickness portion 28a.

1. A device for supporting a semiconductor substrate, said device comprising a sample-holder attached to a treatment chamber including a cooling system and electrical connection means, wherein said device further comprises an intermediate element fixed to said sample-holder by electrostatic means or by means of clamps and electrically and thermally connected to said sample-holder, said intermediate element being removable, having sufficient stiffness to allow manipulation of a thinned substrate that it supports, and including
a base comprising a first material having a higher conductivity than said substrate,
a first layer covering said base and comprising a second material having a high dielectric strength,
first and second electrodes disposed on said first layer, and
a second layer covering said first layer and said electrodes and comprising of a third material having a high dielectric strength.

2. Device according to claim 1, wherein said first material is a metal.

3. Device according to claim 1, wherein said electrodes are of metal.

4. Device according to claim 1, wherein said first material is a metal, and wherein said electrodes are of metal and wherein said metal is selected from copper and aluminum.

5. Device according to claim 1, wherein each of said first and second electrodes has a respective extension that is covered with said first layer to isolate it from said base and passes through said base as far as its rear face to define two electrical contact points.

6. Device according to claim 1, wherein said second material is an aluminum oxide.

7. Device according to claim 1, wherein said third material is a flexible polymer.

8. Device according to claim 1, wherein said first electrode has substantially the shape of a disc and said second electrode has substantially the shape of a ring surrounding said first electrode.

9. Device according to claim 1, wherein a film of pressurized helium is formed between said intermediate element and said sample-holder.

10. Device according to claim 1, wherein a film of pressurized helium is formed between said intermediate element and said substrate.

11. Device according to claim 1, wherein said intermediate element is fixed to said sample-holder by means of clamps.

12. Device according to claim 11, wherein said intermediate element is a disk of greater diameter than said substrate.

13. Device according to claim 11, wherein said base is at least 1 mm thick.

14. Device according to claim 1, wherein said intermediate element is fixed to said sample-holder by electrostatic means.

15. Device according to claim 14, wherein said sample-holder comprises electrodes between which an electrical voltage may be applied.

16. Device according to claim 14, wherein said intermediate element further comprises:
a third layer covering said base on the side opposite said first layer and comprising a fourth material having a high dielectric strength,
third and fourth electrodes disposed on said third layer, and
a fourth layer covering said third layer and said third and fourth electrodes and comprising a fifth material having a high dielectric strength.

17. Device according to claim 16, wherein said fourth material is an oxide of aluminum Al2O3.

18. Device according to claim 16, wherein said electrodes are of metal.

19. Device according to claim 18, wherein said metal is copper or aluminum.

20. Device according to claim 16, wherein said third electrode has substantially the shape of a disc and said fourth electrode has substantially the shape of a ring surrounding said third electrode.

21. Device according to claim 16, wherein each of said third and fourth electrodes has a respective extension that is covered with said third layer to insulate it from said base and passes through said base as far as its rear face to define two electrical contact points.

22. Device according to claim 18, wherein said extensions of said third and fourth electrodes are common with the extensions of said first and second electrodes, respectively.

23. Device according to claim 16, wherein said fifth material is a flexible polymer.

24. A method of manipulating a semiconductor substrate by means of a device according to claim 1, said method comprising the following steps:
said substrate is fixed to an intermediate element by electrostatic means,
said intermediate element carrying said substrate is introduced into a treatment chamber,
said intermediate element is fixed to a sample-holder attached to said chamber and including a cooling system and means for electrical connection to said intermediate element,
said substrate is treated in a plasma medium in a vacuum,
said sample-holder is detached from said intermediate element carrying the treated substrate, and
said substrate is removed from said intermediate element.

25. The method claimed in claim 24, wherein said intermediate element is fixed to said sample-holder by electrostatic means.

26. The method claimed in claim 24, wherein said intermediate element is fixed to said sample-holder by clamps.
